(19) United States
(12) Patent Application Publication
(10) Pub. No.: US 2023/0286024 A9
(43) Pub. Date: Sep. 14, 2023

(54) SEMICONDUCTOR MACHINE CLEANING SYSTEM AND SEMICONDUCTOR MACHINE CLEANING METHOD

(71) Applicant: CHANGXIN MEMORY TECHNOLOGIES, INC., Hefei City, Anhui (CN)

(72) Inventor: WenHao HSU, Hefei City, Anhui (CN)

(21) Appl. No.: 17/438,860

(22) PCT Filed: Jun. 17, 2021
(86) PCT No.: PCT/CN2021/100739

§ 371 Date: Sep. 13, 2021

(30) Foreign Application Priority Data
Aug. 21, 2020 (CN) 202010849829.4

(51) Int. Cl. B08B 5/04; G03F 7/20; H01L 21/67

(52) U.S. Cl. CPC B08B 5/04; G03F 7/70925; H01L 21/67028

(57) ABSTRACT

Embodiments of the present disclosure provide a semiconductor machine cleaning system and a semiconductor machine cleaning method. The semiconductor machine cleaning system includes: an acquisition module, configured to determine whether a semiconductor machine has contamination particles thereon, and to acquire position information of the contamination particles; and a cleaning module, configured to clean the contamination particles based on the position information before the semiconductor machine executes a next manufacturing process; where the contamination particles are cleaned by means of pressure extraction.

### CROSS-REFERENCE TO RELATED APPLICATIONS

The present disclosure claims the priority to Chinese Patent Application 202010849829.4, titled “SEMICONDUCTOR MACHINE CLEANING SYSTEM AND SEMICONDUCTOR MACHINE CLEANING METHOD”, filed on Aug. 21, 2020, which is incorporated herein by reference in its entirety.

### TECHNICAL FIELD

The present disclosure relates to, but is not limited to, a semiconductor machine cleaning system and a semiconductor machine cleaning method.

### BACKGROUND

Exposure is one of the most important processes in the etching process, which directly affects the stability of electrical performance of a device. However, particle defects occur on backs of some wafers before exposure due to process problems. Relatively large contamination particles falls onto a machine before and after the exposure of the wafers having the particle defects, and the contamination particles remain on the machine to contaminate the machine, resulting in an increase in error during wafer exposure through the machine and then revenue loss of wafers.

The inventors found: the current method for cleaning the contamination particles on the machine may cause mechanical damage to the machine, so as to shorten the service life of the machine and increase the production cost.

### SUMMARY

The following is the summary of subject matters detailed in the present disclosure. The summary is not intended to limit the protection scope of the claims.

Embodiments of the present disclosure provide a semiconductor machine cleaning system and a semiconductor machine cleaning method, which clean a semiconductor machine by pressure extraction to clean up contamination particles on the machine without mechanical damage to the machine, thereby reducing the revenue loss of wafers and lowering the production cost of the wafers.

An embodiment of the present disclosure provides a semiconductor machine cleaning system, comprising: an acquisition module, configured to determine whether there are contamination particles on the semiconductor machine, and to acquire position information of the contamination particles; and a cleaning module, configured to clean the contamination particles based on the position information before the semiconductor machine executes a next manufacturing process; wherein the contamination particles are cleaned by means of pressure extraction.

Compared with the prior art, the acquisition module determines whether there are contamination particles on the semiconductor machine, and acquires position information of the contamination particles, and the semiconductor machine is cleaned based on the position information of the contamination particles by extracting the contamination particles under pressure, so that the cleaning process does not cause mechanical damage to the machine.

In some embodiments, a detection module, configured to detect a flatness of the semiconductor machine; and a processing module, configured to, based on a result of a flatness detection, determine whether there are contamination particles on the semiconductor machine, and to acquire the position information of the contamination particles. It is convincing to determine by the flatness detection whether there are contamination particles on the semiconductor machine, and positions of the contamination particles acquired by the flatness detection are accurate.

In some embodiments, the detection module comprises a plurality of sensors separately arranged on the semiconductor equipment. An embodiment of the present disclosure provides a first implementation of the detection module.

In some embodiments, the detection module comprises: one or more emitting units, configured to emit light to the semiconductor machine; and one or more receiving units, configured to receive the light reflected by the semiconductor machine; wherein if the light received by the one or more receiving units changes, the contamination particles appear on the semiconductor machine. An embodiment of the present disclosure provides a second implementation of the detection module.

In some embodiments, the number of emitting units is plural, the number of receiving units is plural, and the receiving units correspond to the emitting units one to one; the light emitted by the emitting units to the semiconductor machine is positioning light; and if any receiving unit cannot receive the positioning light, the contamination particles appear on the semiconductor machine. The receiving units and the emitting units are arranged correspondingly, and the emitting units are configured to emit positioning light to some positions on the machine. If the receiving units can receive the positioning light normally, the semiconductor machine does not have contamination particles at corresponding positions. If any receiving unit cannot receive the positioning light normally, the semiconductor machine has contamination particles at the corresponding position, and the reflection direction of the positioning light is changed.

In some embodiments, the processing module further comprises: a first control unit, configured to stop the manufacturing process on the semiconductor machine when there are the contamination particles on the semiconductor machine. When contamination particles are detected on the semiconductor machine, the manufacturing process on the semiconductor machine is stopped in time to prevent lower wafer yield due to the continued process when the semiconductor machine has defects.

In some embodiments, the processing module further comprises: a second control unit, configured to control the cleaning module to clean the contamination particles when there are the contamination particles on the semiconductor machine.

In some embodiments, the controlling the cleaning module to clean the contamination particles comprises: the cleaning module further comprises: a control part and a moving part; the second control unit is configured to send a control signal to the control part based on the position information of the contamination particles; and the control part controls the moving part based on the control signal to move to a position corresponding to the position information, so that the cleaning module cleans the contamination particles. Through the control signal, the cleaning module is controlled to move and clean the contamination particles, which realizes automatic cleaning of the contamination particles on the semiconductor machine.

In some embodiments, the cleaning module comprises: an extraction part, having a first surface and a second surface disposed opposite to each other, the extraction part having a through hole penetrating the first surface and the second surface; and a power part, connected to the extraction part for extracting the contamination particles via the through hole. An embodiment of the present disclosure provides a specific structure of the cleaning module that cleans contamination particles by means of pressure extraction.

In some embodiments, the extraction part comprises at least an air extraction pipe, and the power part comprises at least an air extraction device. An embodiment of the present disclosure provides a specific structure of the cleaning module.

In some embodiments, the air extraction pipe has a length of 300 mm to 320 mm; the air extraction pipe has an outer diameter of 20 mm to 50 mm; and the air extraction pipe has an inner diameter of 10 mm to 30 mm.

In some embodiments, a material of the air extraction pipe is stainless steel.

In some embodiments, the extraction part comprises: a first sub-extraction part and a second sub-extraction part; the first sub-extraction part and the second sub-extraction part are arranged perpendicular to each other, and a first through hole of the first sub-extraction part is communicated with a second through hole of the second sub-extraction part. The first sub-extracting part and the second sub-extracting part are arranged perpendicular to each other, so that the pipe for extracting contamination particles has an angle to prevent the extracted contamination particles from falling again to cause secondary contamination of the machine.

An embodiment of the present disclosure further provides a method for cleaning a semiconductor equipment, comprising: determining whether there are contamination particles on a semiconductor machine; if there are the contamination particles, obtaining position information of the contamination particles; and cleaning, by the above-mentioned semiconductor machine cleaning system, the contamination particles based on the position information before a next manufacturing process starts.

In some embodiments, the determining whether there are contamination particles on a semiconductor machine comprises: detecting a flatness of a surface of the semiconductor machine, and determining, based on a result of a flatness detection, whether there are the contamination particles on the semiconductor machine; and the obtaining position information of the contamination particles comprises: obtaining the position information based on the result of the flatness detection.

In some embodiments, if there are the contamination particles, the method further comprises: stopping the current manufacturing process.

In some embodiments, before the cleaning, by the semiconductor machine cleaning system, the contamination particles based on the position information before a next manufacturing process starts, the method further comprises: generating a control signal based on the position information; and controlling, based on the control signal, the semiconductor machine cleaning system to clean the contamination particles.

Compared with the prior art, the cleaning process does not cause mechanical damage to the system by determining whether there are contamination particles on the semiconductor system, acquiring position information of the contamination particles, and cleaning the semiconductor system based on the position information of the contamination particles by extracting the contamination particles under pressure.

Other aspects will be apparent upon reading and understanding the accompanying drawings and detailed descriptions.

### BRIEF DESCRIPTION OF THE DRAWINGS

The accompanying drawings incorporated into the description and constituting a part of the description illustrate the embodiments of the present disclosure, and are used together with the description to explain the principles of the embodiments of the present disclosure. In these drawings, similar reference numerals are used to indicate similar elements. The drawings in the following description are some embodiments of the present disclosure, but not all embodiments. For those of ordinary skill in the art, other drawings can be obtained based on these drawings without any creative efforts.

One or more embodiments are illustrated by the figures in the corresponding drawings, and the figures in the drawings do not constitute scale limitations, unless otherwise stated.

FIGS. 1 to 3 are schematic structure diagrams of a semiconductor machine cleaning system according to a first embodiment of the present disclosure;

FIGS. 4 and 5 are principle diagrams corresponding to a machine flatness detection method according to a first embodiment of the present disclosure;

FIG. 6 is a schematic structure diagram of a cleaning module according to a first embodiment of the present disclosure;

FIGS. 7 and 8 are principle diagrams of implementing automatic cleaning according to a first embodiment of the present disclosure;

FIG. 9 is a schematic structure diagram of another cleaning module according to a first embodiment of the present disclosure; and

FIG. 10 is a schematic flowchart of a semiconductor machine cleaning method according to a second embodiment of the present disclosure.

### DETAILED DESCRIPTION

At present, the method for cleaning contamination particles on a machine may cause mechanical damage to the machine, so as to shorten the service life of the machine and increase the production cost.

A first embodiment of the present disclosure provides a semiconductor machine cleaning system, comprising: an acquisition module, configured to determine whether a semiconductor machine has contamination particles thereon, and to acquire position information of the contamination particles; and a cleaning module, configured to clean the contamination particles based on the position information before the semiconductor machine executes a next manufacturing process; wherein the contamination particles are cleaned by means of pressure extraction.

In order to make the objectives, technical solutions and advantages of the embodiments of the present disclosure clearer, the embodiments of the present disclosure will be described in detail below with reference to the accompanying drawings. However, a person of ordinary skill in the art can understand that, in each embodiment of the present disclosure, many technical details are proposed in order to enable a reader to better understand the present disclosure. However, the technical solutions of the present disclosure can also be implemented without these technical details and various variations and modifications based on the following embodiments. The division of the following embodiments is for convenience of description, and should not constitute any limitation to the specific implementation of the present disclosure, and the various embodiments can be combined with each other and mutually cited under the premise of no contradiction.

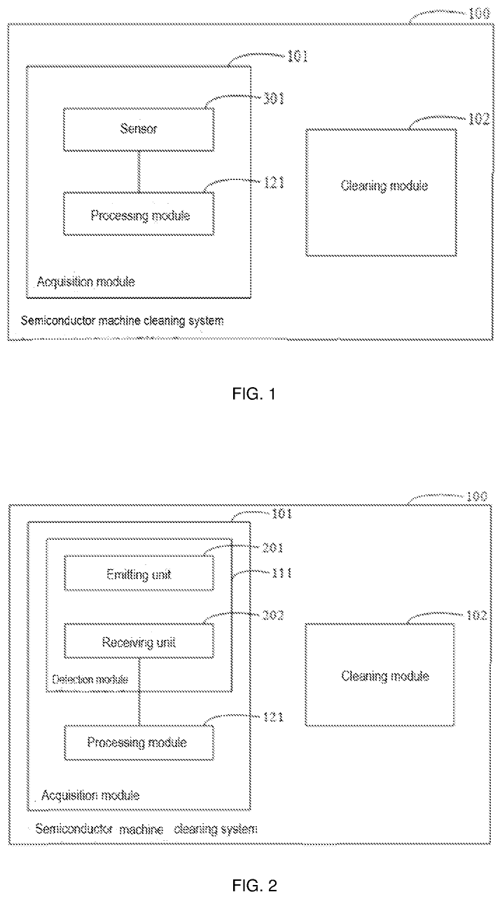

FIGS. 1 to 3 are schematic structure diagrams corresponding to a semiconductor machine cleaning system according to an embodiment of the present disclosure. The semiconductor machine cleaning system in this embodiment will be described in detail below with reference to the accompanying drawings.

Referring to FIG. 1, a semiconductor machine cleaning system 100 comprises: an acquisition module 101 configured to acquire positions of contamination particles, and a cleaning module 102 configured to clean the contamination particles.

The acquiring module 101 is configured to determine whether there are contamination particles on a semiconductor machine, and to acquire the position information of the contamination particles if there are contamination particles.

The cleaning module 102 is configured to clean the contamination particles based on the position information before the semiconductor machine executes a next manufacturing process, and the contamination particles are cleaned by means of pressure extraction.

It should be noted that the step of the acquisition module 101 determining whether there are contamination particles on the semiconductor machine is implemented when the semiconductor machine executes a manufacturing process or after the current manufacturing process is completed. Before the next manufacturing process starts, if there are contamination particles on the semiconductor machine, the contamination particles are cleaned to ensure that the semiconductor machine is a clean machine when the wafer manufacturing process starts.

In this embodiment, referring to FIG. 2, the acquisition module 101 comprises: a detection module 111 configured to detect whether there are contamination particles on the semiconductor machine, and a processing module 121 configured to acquire the position information of the contamination particles.

The detection module 111 is configured to detect the flatness of the semiconductor machine. The processing module 121 determines, based on the result of flatness detection, whether there are contamination particles on the semiconductor machine, and acquires the position information of the contamination particles.

In an example, referring to FIG. 1, the detection module is implemented by sensors 301. The detection module 111 comprises a plurality of sensors 301 separately arranged on the semiconductor machine, such as a distance sensor separately arranged on the top of the semiconductor machine and configured to detect the distance between the distance sensor and the surface of the semiconductor machine. If there are contamination particles, the distance between the distance sensor and the surface of the semiconductor machine, acquired by the distance sensor at the corresponding position, will become short, so that an analog signal acquired by the distance sensor changes. Then the analog signal is digitized to obtain the position information of the contamination particles.

In an example, referring to FIG. 2, the detection module 111 comprises an emitting unit 201 configured to emit light and a receiving unit 202 configured to receive reflected light.

The emitting unit 201 is configured to emit light to the semiconductor machine, and the receiving unit 202 is configured to receive the light reflected by the semiconductor machine. If the light received by the receiving unit 202 changes, contamination particles appear on the semiconductor machine.

Assuming that there are no contamination particles on the semiconductor machine, the light received by the receiving unit 202 is a first light collection. When there are contamination particles on the semiconductor machine, the light originally irradiated onto the semiconductor machine to be reflected is irradiated to the surface of the contamination particles, and the contamination particles change the reflection direction of part of the light, so that the light received by the receiving unit 202 is a second light collection. The second light collection changes compared to the first light collection. It is known according to the change of the received light that contamination particles appear on the semiconductor machine. In addition, the receiving unit 202 obtains abnormally reflected light based on the difference between the second light collection and the first light collection, so as to obtain that there are contamination particles on the top surface of the semiconductor machine at the corresponding position. The receiving unit 202 determines that the second light collection changes compared to the first light collection, based on conditions such as light intensity or light type.

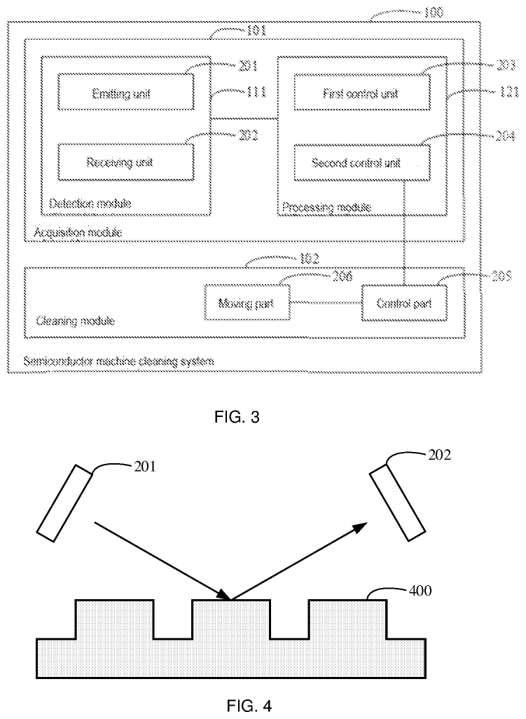

In a specific example, the number of emitting units 201 is plural, the number of receiving units 202 is plural, and the receiving units 202 correspond to the emitting units 201 one to one. Referring to FIGS. 4 and 5, the light emitted from the emitting unit 201 to the semiconductor machine 400 is positioning light, which is light with good directionality, for example, laser. The plurality of emitting units 201 emit positioning light to different positions on the surface of the semiconductor machine 400, then the receiving units 202 in one-to-one correspondence receive the positioning light, whether there are contamination particles 401 on the surface of the semiconductor machine 400 is determined based on whether the receiving units 202 can receive the positioning light, and the positions of the contamination particles 401 are acquired.

Referring to FIG. 3, in this embodiment, the processing module 121 further comprises a first control unit 203, which is configured to stop the manufacturing process on the semiconductor machine when there are contamination particles on the semiconductor machine.

That is, the semiconductor machine cleaning system provided in this embodiment detects contamination particles when the semiconductor machine executes the current manufacturing process, and the manufacturing process on the semiconductor machine is immediately stopped when contamination particles are detected on the surface of the semiconductor machine. By detecting contamination particles when the semiconductor machine executes the manufacturing process, process yield problems caused by contamination particles are avoided.

In this embodiment, the processing module 121 further comprises a second control unit 204, which is configured to control the cleaning module 102 to clean the contamination particles when there are contamination particles on the semiconductor machine.

That is, after the semiconductor machine cleaning system provided in this embodiment detects that contamination particles appear on the top of the semiconductor machine, the second control unit 204 controls the cleaning module 102 to clean the contamination particles. A mode of automatically cleaning contamination particles based on the detection results is realized, manual participation in cleaning contamination particles is avoided, and the labor cost required for the manufacturing process is thereby saved.

The cleaning module 102 further comprises a control part 205 and a moving part 206. The second control unit 204 is configured to send a control signal to the control part 205 based on the position information of the contamination particles, and the control part 205 controls, based on the control signal, the moving part 206 to move to a position corresponding to the control signal, so that the cleaning module 102 cleans the contamination particles.

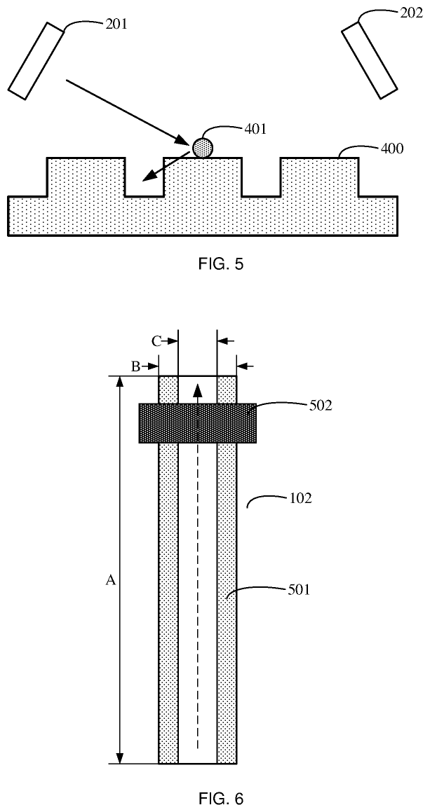

In this embodiment, referring to FIG. 6, the cleaning module 102 comprises an extraction part 501 and a power part 502, the extraction part 501 has a first surface and a second surface disposed opposite to each other, and the extraction part 501 has a through hole penetrating the first surface and the second surface.

The first surface is a surface close to the semiconductor machine, and the second surface is a surface away from the semiconductor machine. The through hole is a channel via which the extraction part 501 cleans contamination particles by means of pressure extraction, and the power part 502 arranged on the extraction part 501 is used to extract contamination particles via the through hole.

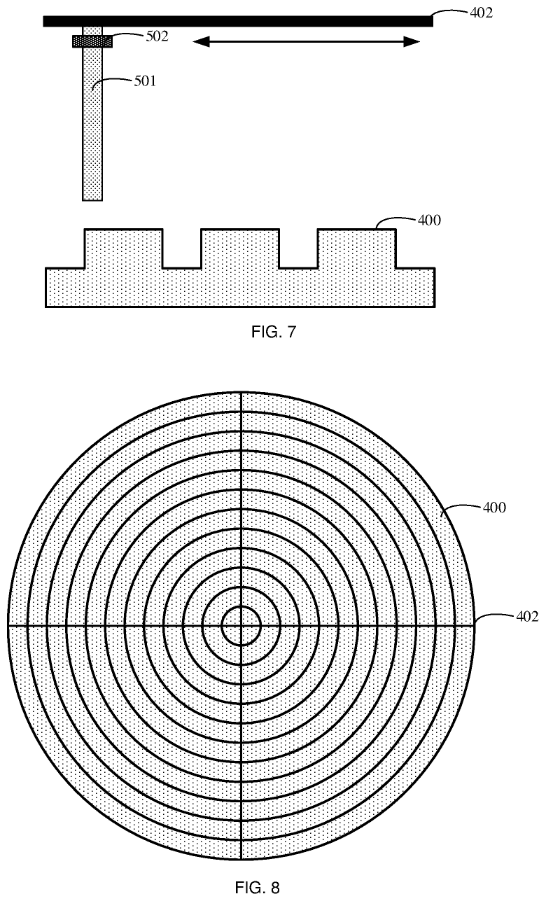

Referring to FIGS. 7 and 8, a support rail 402 is arranged on the top of the semiconductor machine 400. The support rail is arranged as shown in FIG. 8. The cleaning module moves on the support rail 402 through the moving part, so as to accurately move to the positions of contamination particles according to the control signal.

In an example, the extraction part 501 at least comprises an extraction pipe, and the power part 502 at least comprises an extraction device. The extraction part 501 has a length of 300 mm to 320 mm; the extraction part 501 has an outer diameter of 20 mm to 50 mm; and the extraction part 501 has an inner diameter of 10 mm to 30 mm. The material of the extraction part 501 is stainless steel. The extraction part 501 is made of stainless steel to prevent the extraction part 501 from rusting to contaminate the semiconductor machine.

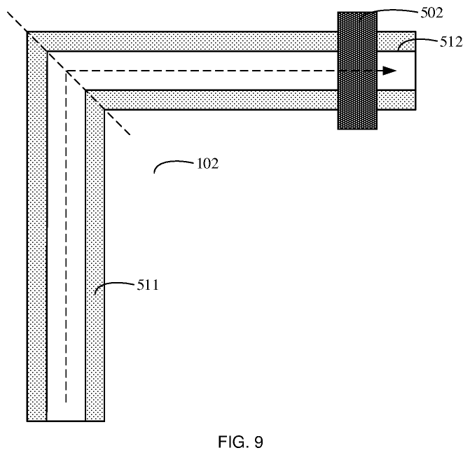

It should be noted that, in other embodiments, referring to FIG. 9, the extraction part 501 further comprises a first sub-extraction part 511 and a second sub-extraction part 512. Specifically, the first sub-extraction part 511 and the second sub-extraction part 512 are arranged perpendicular to each other, and a first through hole of the first sub-extraction part 511 is communicated with a second through hole of the second sub-extraction part 512. The first sub-extraction part 511 and the second sub-extraction part 512 are arranged perpendicular to each other, so that the pipe for extracting contamination particles has an angle to prevent the extracted contamination particles from falling again to cause secondary contamination of the machine.

Compared with the prior art, the acquisition module determines whether there are contamination particles on the semiconductor machine, and acquires position information of the contamination particles, and the semiconductor machine is cleaned based on the position information of the contamination particles by means of pressure extraction, so that the cleaning process does not cause mechanical damage to the machine.

It is worth mentioning that the modules involved in this embodiment are all logical modules. In practical applications, a logical unit can be a physical unit, a part of a physical unit, or a combination of a plurality of physical units. Moreover, in order to highlight the innovative part of the present disclosure, this embodiment does not introduce units that are not closely related to solving the technical problems proposed by the present disclosure, but this does not indicate that there are no other units in this embodiment.

A second embodiment of the present disclosure relates to a semiconductor machine cleaning method.

The semiconductor machine cleaning method comprises: determining whether there are contamination particles on a semiconductor machine; if there are contamination particles, obtaining position information of the contamination particles; and cleaning, by the above-mentioned semiconductor machine cleaning system, the contamination particles based on the position information before a next manufacturing process starts.

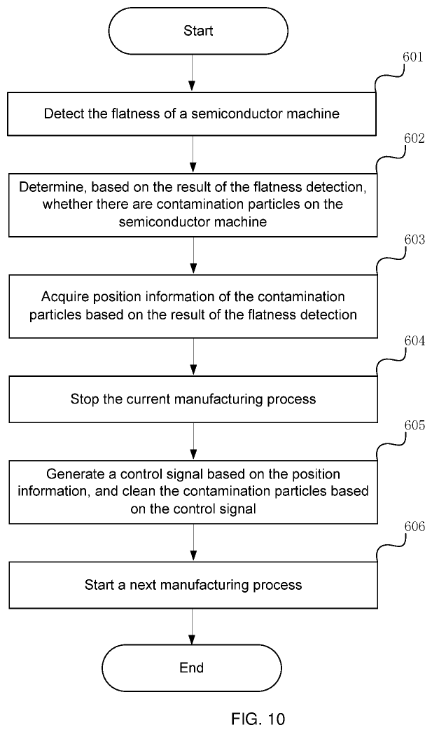

Referring to FIG. 10, the semiconductor machine cleaning method provided in this embodiment will be described in detail below with reference to the accompanying drawing. The parts that are the same as or corresponding to the first embodiment will not be described in detail below.

Step 601, the flatness of a semiconductor machine is detected.

Step 602, whether there are contamination particles on the semiconductor machine is determined based on the result of flatness detection.

Step 603, position information of the contamination particles is acquired based on the result of flatness detection.

In an example, the flatness of the semiconductor machine is detected by sensors.

A plurality of sensors are arranged on the semiconductor machine, such as a distance sensor separately arranged on the top of the semiconductor machine and configured to detect the distance between the distance sensor and the surface of the semiconductor machine. If there are contamination particles, the distance between the distance sensor and the surface of the semiconductor machine, acquired by the distance sensor at the corresponding position, will become short, so that an analog signal acquired by the distance sensor changes. Then the analog signal is digitized to obtain the position information of the contamination particles.

In an example, the flatness of the semiconductor machine is detected by an emitting unit for emitting light and a receiving unit for receiving reflected light.

The emitting unit is configured to emit light to the semiconductor machine, and the receiving unit is configured to receive the light reflected by the semiconductor machine. If the light received by the receiving unit changes, contamination particles appear on the semiconductor machine.

Assuming that there are no contamination particles on the semiconductor machine, the light received by the receiving unit is a first light collection. When there are contamination particles on the semiconductor machine, the light originally irradiated onto the semiconductor machine to be reflected is irradiated to the surface of the contamination particles, and the contamination particles change the reflection direction of part of the light, so that the light received by the receiving unit is a second light collection. The second light collection changes compared to the first light collection. It is known according to the change of the received light that contamination particles appear on the semiconductor machine. In addition, the receiving unit obtains abnormally reflected light based on the difference between the second light collection and the first light collection, so as to obtain that there are contamination particles on the top surface of the semiconductor machine at the corresponding position. The receiving unit determines that the second light collection changes compared to the first light collection, based on conditions such as light intensity or light type.

In an optional example, the number of emitting units is plural, the number of receiving units is plural, and the receiving units correspond to the emitting units one to one. The light emitted from the emitting unit to the semiconductor machine is positioning light, which is light with good directionality, for example, laser. The plurality of emitting units emit positioning light to different positions on the surface of the semiconductor machine, then the receiving units in one-to-one correspondence receive the positioning light, whether there are contamination particles on the surface of the semiconductor machine is determined based on whether the receiving units can receive the positioning light, and the positions of the contamination particles are acquired.

Step 604, the current manufacturing process is stopped.

The semiconductor machine cleaning system provided in this embodiment detects contamination particles when the semiconductor machine executes the current manufacturing process, and the manufacturing process on the semiconductor machine is immediately stopped when contamination particles are detected on the surface of the semiconductor machine. By detecting contamination particles when the semiconductor machine executes the manufacturing process, process yield problems caused by contamination particles are avoided.

Step 605, a control signal is generated based on the position information, and the contamination particles are cleaned based on the control signal.

The control signal is sent to the cleaning device based on the position information of the contamination particles, so that the cleaning device moves to a position corresponding to the control signal based on the control signal, and the cleaning module 102 cleans the contamination particles.

Step 606, a next manufacturing process starts.

After the cleaning device cleans the contamination particles on the semiconductor machine, the semiconductor machine starts to execute the next wafer manufacturing process, so as to ensure that the semiconductor machine is a clean machine when the wafer manufacturing process starts.

Compared with the prior art, the cleaning process does not cause mechanical damage to the machine by determining whether there are contamination particles on the semiconductor machine, acquiring position information of the contamination particles, and cleaning the semiconductor machine based on the position information of the contamination particles by extracting the contamination particles under pressure.

The division of the above various steps is only for clarity of description. When implemented, the steps can be combined into one step or some steps can be split into a plurality of steps, as long as they comprise the same logical relationship, they fall all within the protection scope of this disclosure. Insignificant modifications added or insignificant designs introduced to the process without changing the core design of the process all fall within the protection scope of this disclosure.

Since the first embodiment corresponds to this embodiment, this embodiment can be implemented in cooperation with the first embodiment. Relevant technical details mentioned in the first embodiment are still valid in this embodiment, and the technical effects that can be achieved in the first embodiment can also be achieved in this embodiment. In order to reduce repetition, details are not described herein again. Correspondingly, the relevant technical details mentioned in this embodiment can also be applied to the first embodiment.

A person skilled in the art would readily conceive of other embodiments of the present disclosure after considering the disclosure of the description and practice. The present disclosure is intended to cover any variations, uses or adaptive changes of the present disclosure. These variations, uses or adaptive changes follow the general principle of the present disclosure and comprise common general knowledge or conventional technical means in the technical field that are not disclosed in the present disclosure. The description and the embodiments are merely regarded as exemplary, and the real scope and spirit of the present disclosure are pointed out by the following claims.

It should be understood that the present disclosure is not limited to the precise structure described above and shown in the drawings, and various modifications and changes can be made without departing from its scope. The scope of the present disclosure is only limited by the appended claims.

### INDUSTRIAL APPLICABILITY

In the present disclosure, whether there are contamination particles on a semiconductor machine is determined, position information of the contamination particles is acquired, and the contamination particles are cleaned by means of pressure extraction based on the acquired position information before the semiconductor machine executes a next manufacturing process, so that accurate cleaning is achieved without causing mechanical damage to the machine.

1. A semiconductor machine cleaning system, comprising:
an acquisition module, configured to determine whether there are contamination particles on the semiconductor machine, and to acquire position information of the contamination particles; and
a cleaning module, configured to clean the contamination particles based on the position information before the semiconductor machine executes a next manufacturing process;
wherein the contamination particles are cleaned by means of pressure extraction.

2. The semiconductor machine cleaning system according to claim 1, wherein the acquisition module comprises:
a detection module, configured to detect a flatness of the semiconductor machine; and
a processing module, configured to, based on a result of a flatness detection, determine whether there are contamination particles on the semiconductor machine, and to acquire the position information of the contamination particles.

3. The semiconductor machine cleaning system according to claim 2, wherein the detection module comprises a plurality of sensors separately arranged on the semiconductor machine.

4. The semiconductor machine cleaning system according to claim 2, wherein the detection module comprises:
one or more emitting units, configured to emit light to the semiconductor machine; and
one or more receiving units, configured to receive the light reflected by the semiconductor machine;
wherein if the light received by the one or more receiving units changes, the contamination particles appear on the semiconductor machine.

5. The semiconductor machine cleaning system according to claim 4, wherein the number of emitting units is plural, the number of receiving units is plural, and the receiving units correspond to the emitting units one to one;
the light emitted by the emitting units to the semiconductor machine is positioning light; and
if any receiving unit cannot receive the positioning light, the contamination particles appear on the semiconductor machine.

6. The semiconductor machine cleaning system according to claim 2, wherein the processing module further comprises: a first control unit, configured to stop the manufacturing process on the semiconductor machine when there are the contamination particles on the semiconductor machine.

7. The semiconductor machine cleaning system according to claim 2, wherein the processing module further comprises: a second control unit, configured to control the cleaning module to clean the contamination particles when there are the contamination particles on the semiconductor machine.

8. The semiconductor machine cleaning system according to claim 7, wherein the controlling the cleaning module to clean the contamination particles comprises:
the cleaning module further comprises: a control part and a moving part;
the second control unit is configured to send a control signal to the control part based on the position information of the contamination particles; and
the control part controls the moving part based on the control signal to move to a position corresponding to the position information, so that the cleaning module cleans the contamination particles.

9. The semiconductor machine cleaning system according to claim 1, wherein the cleaning module comprises:
an extraction part, having a first surface and a second surface disposed opposite to each other, the extraction part having a through hole penetrating the first surface and the second surface; and
a power part, connected to the extraction part for extracting the contamination particles via the through hole.

10. The semiconductor machine cleaning system according to claim 9, wherein the extraction part comprises at least an air extraction pipe, and the power part comprises at least an air extraction device.

11. The semiconductor machine cleaning system according to claim 10, wherein the air extraction pipe has a length of 300 mm to 320 mm; the air extraction pipe has an outer diameter of 20 mm to 50 mm; and the air extraction pipe has an inner diameter of 10 mm to 30 mm.

12. The semiconductor machine cleaning system according to claim 10, wherein a material of the air extraction pipe is stainless steel.

13. The semiconductor machine cleaning system according to claim 9, wherein the extraction part comprises: a first sub-extraction part and a second sub-extraction part;
the first sub-extraction part and the second sub-extraction part are arranged perpendicular to each other, and a first through hole of the first sub-extraction part is communicated with a second through hole of the second sub-extraction part.

14. A semiconductor machine cleaning method, comprising:
determining whether there are contamination particles on a semiconductor machine;
if there are the contamination particles, obtaining position information of the contamination particles; and
cleaning, by the semiconductor machine cleaning system according to claim 1, the contamination particles based on the position information before a next manufacturing process starts.

15. The semiconductor machine cleaning method according to claim 14, wherein the determining whether there are contamination particles on a semiconductor machine comprises:
detecting a flatness of a surface of the semiconductor machine, and
determining, based on a result of a flatness detection, whether there are the contamination particles on the semiconductor machine; and
the obtaining position information of the contamination particles comprises: obtaining the position information based on the result of the flatness detection.

16. The semiconductor machine cleaning method according to claim 14, wherein if there are the contamination particles, the method further comprises: stopping the current manufacturing process.

17. The semiconductor machine cleaning method according to claim 14, wherein before the cleaning, by the semiconductor machine cleaning system, the contamination particles based on the position information before a next manufacturing process starts, the method further comprises:
generating a control signal based on the position information; and
controlling, based on the control signal, the semiconductor machine cleaning system to clean the contamination particles.
